(19) United States
(12) Patent Application Publication
(10) Pub. No.: US 2025/0140753 A1
(43) Pub. Date: May 1, 2025

(54) STACKED SEMICONDUCTOR DEVICE WITH SEMICONDUCTOR DIES OF VARIABLE SIZE

(71) Applicant: Micron Technology, Inc., Boise, ID (US)

(72) Inventors: Bharat Bhushan, Taichung (TW); Kunal R. Parekh, Boise, ID (US); Akshay N. Singh, Boise, ID (US); Eiichi Nakano, Boise, ID (US)

(21) Appl. No.: 18/920,749

(22) Filed: Oct. 18, 2024

Related U.S. Application Data
(60) Provisional application No. 63/546,607, filed on Oct. 31, 2023.

(51) Int. Cl. H01L 25/065; H01L 23/00; H01L 25/18

(52) U.S. Cl. CPC H01L 25/0657; H01L 24/08; H01L 24/80; H01L 25/18; H01L 2224/08225; H01L 2224/80895; H01L 2225/06541; H01L 2924/1431

(57) ABSTRACT

A semiconductor device assembly is disclosed. The semiconductor device assembly includes a first semiconductor die and second semiconductor dies and an additional semiconductor component coupled with the logic die. Dielectric peripheral material is disposed along sidewalls of the first die and extends beyond a first footprint of the first die. A gap fill material is disposed at the first die and at the dielectric peripheral material beyond a second footprint of the second semiconductor dies and a third footprint of the additional semiconductor component such that the gap fill material at least partially surrounds the second semiconductor dies and the additional semiconductor component.

### CROSS-REFERENCE TO RELATED APPLICATION(S)

The present application claims priority to U.S. Provisional Patent Application No. 63/546,607, filed Oct. 31, 2023, the disclosure of which is incorporated herein by reference in its entirety.

### TECHNICAL FIELD

The present disclosure generally relates to semiconductor device assemblies and more particularly relates to a stacked semiconductor device with semiconductor dies of variable size.

### BACKGROUND

Microelectronic devices generally have a die (i.e., a chip) that includes integrated circuitry with a high density of very small components. Typically, dies include an array of very small bond pads electrically coupled to the integrated circuitry. The bond pads are external electrical contacts through which the supply voltage, signals, etc., are transmitted to and from the integrated circuitry. After dies are formed, they are “packaged” to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals and encapsulating the dies to protect them from environmental factors (e.g., moisture, particulates, static electricity, and physical impact).

### BRIEF DESCRIPTION OF THE DRAWINGS

FIG. 1A illustrates a simplified schematic cross-sectional view of a semiconductor device assembly in accordance with an embodiment of the present technology.

FIG. 1B illustrates a simplified schematic plan view of a wafer-level semiconductor device assembly in accordance with an embodiment of the present technology.

FIG. 2A illustrates a simplified schematic cross-sectional view of a semiconductor device assembly in accordance with an embodiment of the present technology.

FIG. 2B illustrates a simplified schematic plan view of a wafer-level semiconductor device assembly in accordance with an embodiment of the present technology.

FIGS. 3-11 illustrate simplified schematic perspective and cross-sectional views of a series of steps for fabricating semiconductor device assemblies in accordance with embodiments of the present technology.

FIG. 12 illustrates a schematic view of a system that includes a semiconductor device assembly configured in accordance with an embodiment of the present technology.

FIG. 13 illustrates a method for fabricating a semiconductor device assembly in accordance with an embodiment of the present technology.

### DETAILED DESCRIPTION

Semiconductor device packages are used to implement multiple semiconductor dies into a single, unitary structure that can provide functionality to an electronic device. For example, multiple semiconductor dies can be stacked on top of one another to enable additional circuit components to be implemented within a package without increasing the footprint of the package. As semiconductor devices are designed for increasingly complex applications, the semiconductor dies implemented within packages can become larger and more complex, which increases the likelihood of these dies having defects that decrease yield.

Often, semiconductor device packages are assembled at the wafer level to enable simultaneous assembly of multiple semiconductor devices. For example, individual semiconductor dies or stacks of semiconductor dies (e.g., memory dies) can be attached to different semiconductor dies (e.g., logic dies) within a wafer. When defective dies are detected within the wafer, dummy semiconductor components that do not include functional circuitry can be coupled with the defective dies of the wafer while functional semiconductor dies can be coupled with functional semiconductor dies of the wafer. In this way, continuity can be maintained across the wafer without wasting functional semiconductor dies within packages that will be inoperable due to one or more of the semiconductor dies within being defective. This process, however, still wastes assembly processes and dummy components on inoperable devices, which are increasingly likely in low-yield semiconductor dies.

Moreover, previous assembly techniques that stack similarly sized dies onto one another can be incapable of implementing semiconductor device packages designed for some complex applications. For example, a memory die or stack of memory dies can be stacked onto a similarly sized logic die. When large logic dies are implemented that are much greater in size than the memory dies stacked thereon, stacking only a single memory die or a single stack of memory dies onto the logic die can waste space and create a lack of continuity across the package. Thus, additional assembly techniques can improve the implementation of some semiconductor device packages, particularly those that utilize low-yield dies or include dies of different sizes stacked onto one another.

One such technique provides for a stacked semiconductor device with semiconductor dies of variable size. The semiconductor device can be fabricated at the wafer level by reconstructing a wafer from singulated “known good dies.” For example, logic dies can be singulated from a logic wafer and tested to determine their operability. Once determined as operable, the logic dies can be attached to a carrier wafer and surrounded by a gap fill material (e.g., a dielectric material or oxide). In this way, the logic dies within the reconstructed wafer can be determined as functional before additional semiconductor dies are attached, thus improving yield. A stack of semiconductor dies and an additional semiconductor component can be coupled with each of the logic dies within the reconstructed wafers. In aspects, the additional semiconductor component can be an additional stack of semiconductor dies or a dummy semiconductor component void of functional circuitry. The additional stack of semiconductor dies or the additional semiconductor component can similarly be tested for functionality before being coupled with the logic dies. An additional gap fill material can be disposed around the stack of semiconductor dies and the additional semiconductor component. The individual logic dies can then be singulated between the gap fill material and the additional gap fill material to singulate a single semiconductor device. The semiconductor device can have peripheral portions formed by the gap fill material and the additional gap fill material that extend along sidewalls of the semiconductor dies.

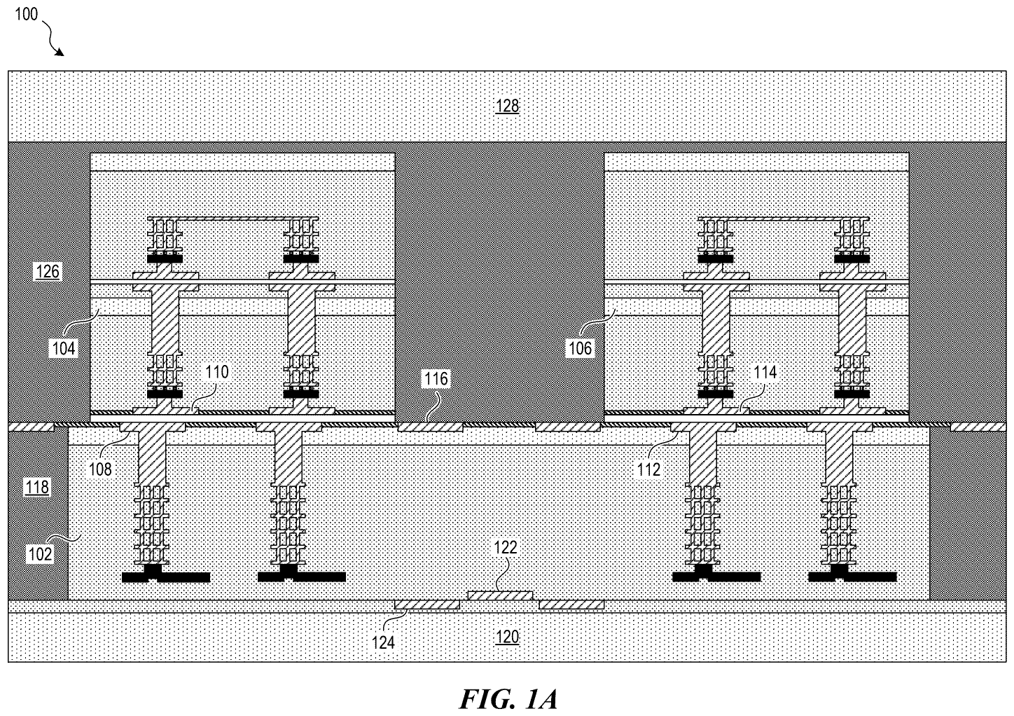

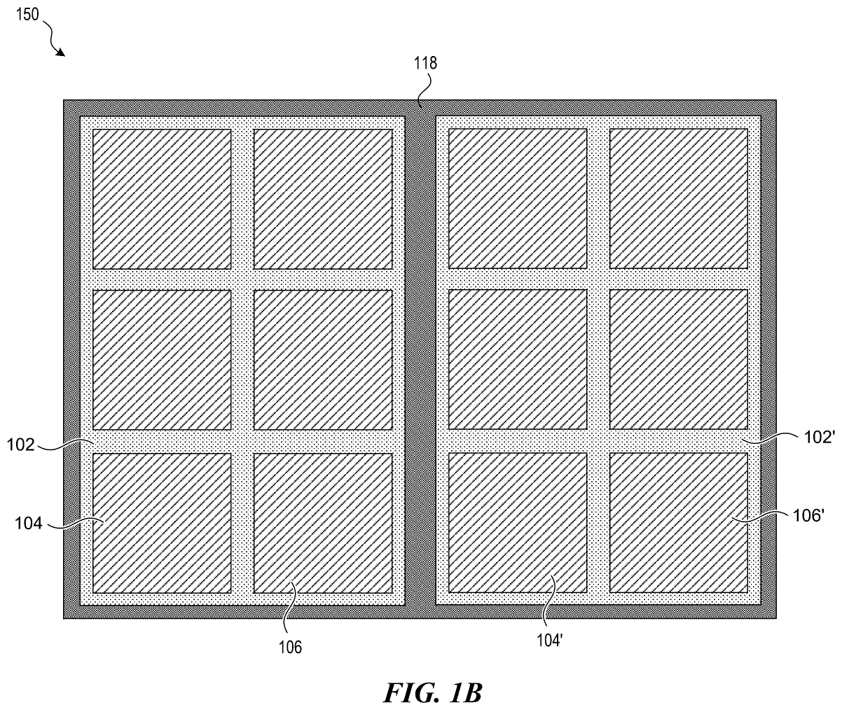

FIG. 1A illustrates a simplified schematic cross-sectional view of a semiconductor device assembly 100 in accordance with an embodiment of the present technology. The semiconductor device assembly 100 includes a semiconductor die 102 and a one or more semiconductor dies 104 (e.g., a stack of semiconductor dies) and one or more semiconductor dies 106 (e.g., a stack of semiconductor dies) assembled onto the semiconductor die 102. The semiconductor dies 104 can be assembled onto the semiconductor die 102 at a first lateral location, and the semiconductor dies 106 can be assembled onto the semiconductor die 102 at a second lateral location different from the first lateral location. In aspects, the semiconductor die 102 can include a logic die that implements a processor, a central processing unit (CPU), a graphical processing unit (GPU), an interface (IF) controller, or the like. The semiconductor dies 104 and the semiconductor dies 106 can implement memory dies that store data to be operated on by the logic die. In some cases, the memory dies can act as a main memory or a dedicated memory accessible by the logic die. The semiconductor dies 104 and the semiconductor dies 106 can implement the same type of memory or different types of memory. For example, the semiconductor dies 104 can include dynamic random-access memory (DRAM), the semiconductor dies 106 can include static random-access memory (SRAM), and additional semiconductor dies can include NOT-AND (NAND) memory.

The semiconductor dies 104 and the semiconductor dies 106 can electrically and mechanically couple to the semiconductor die 102. For example, interconnects (e.g., copper-copper (Cu—Cu) interconnects) can be formed (e.g., through hybrid bonding) between contacts 108 at the semiconductor die 102 and contacts 110 at the semiconductor dies 104. Similarly, contacts 112 at the semiconductor die 102 and contacts 114 at the semiconductor dies 106 can form interconnects electrically and mechanically coupling the semiconductor die 102 and the semiconductor dies 106. The contacts 108 and the contacts 112 can couple with functional circuitry (e.g., transistors, diodes, resistors, and other components) at a front side of the semiconductor die 102 through connective circuitry (e.g., traces, lines, vias, and through-silicon vias (TSVs)). The contacts 110 and the contacts 114 can similarly couple with functional circuitry at the semiconductor dies 104 and the semiconductor dies 106 through connective circuitry. Thus, the interconnects can electrically couple circuitry at the stack of semiconductor dies 104 and the semiconductor dies 106 with circuitry at the semiconductor die 102. Dielectric material (e.g., dielectric block) at the semiconductor dies 104 and the semiconductor dies 106 can further bond with dielectric material at the semiconductor die 102 to mechanically couple the components. The dielectric material can include silicon oxide, silicon nitride, silicon carbide, silicon carbon nitride, or the like.

The semiconductor die 102 can further include dummy pads 116 implemented similarly to the contacts 108 and the contacts 112 but decoupled from the functional circuitry at the semiconductor die 102. In this way, the dummy pads 116 cannot be used to electrically couple additional components to the semiconductor die 102 such as the contacts 108 and the contacts 112. Instead, the dummy pads 116 can be used to mechanically bond components to the semiconductor die 102 and increase uniformity across a bonding surface of the semiconductor die 102. The dummy pads 116 can be implemented with similar spacing as the contacts 108 and the contacts 112 at locations that are void of contacts, for example, outside the footprints of the semiconductor dies 104 or the semiconductor dies 106. Dummy pads can similarly be implemented on a gap fill material 118 surrounding the semiconductor die 102.

The semiconductor die 102 can be assembled onto a carrier substrate 120 (e.g., through an adhesive or dielectric material) used to reconstruct the semiconductor die 102 and other semiconductor dies into a wafer of semiconductor dies. For example, the semiconductor die 102 and the other semiconductor dies can be attached to the carrier substrate 120 (e.g., through chip-to-wafer bonding), and the gap fill material 118 can be disposed around the semiconductor die 102 and the other semiconductor dies to form a reconstructed wafer. In some cases, the semiconductor die 102 can be attached to the carrier substrate 120 through a fusion bonding process. The gap fill material 118 can include a dielectric material, such as silicon oxide, silicon nitride, silicon carbide, silicon carbon nitride, and so on. In some cases, the gap fill material 118 is an oxide. In some cases, the gap fill material 118 can be disposed at least partially over a distal surface of the semiconductor die 102 opposite the carrier substrate 120. The semiconductor die 102 can be attached to the carrier substrate 120 at the appropriate location through reference to fiducials 122 at the semiconductor die 102 and fiducials 124 at the carrier substrate 120. The surface of semiconductor dies 102 can be exposed as a result of the thinning process at the gap fill material 118. Once the gap fill material 118 is disposed, the semiconductor dies 104 and the semiconductor dies 106 can be attached to the reconstructed wafer at the semiconductor die 102.

A gap fill material 126 similar to the gap fill material 118 can be disposed around the semiconductor dies 104 and the semiconductor dies 106. In one aspect, the gap fill material 126 can be different than gap fill material 118. The gap fill material 118 or the gap fill material 126 can be selected to achieve maximal thermal dissipation from the semiconductor die 102. The gap fill material 126 can be disposed over the semiconductor die 102 and the gap fill material 118 beyond the footprints of the semiconductor dies 104 and the semiconductor dies 106. In some cases, the gap fill material 126 can be disposed over a distal surface of the semiconductor dies 104 and the semiconductor dies 106 opposite the carrier substrate 120.

A lid 128 can be disposed over the semiconductor dies 104 and the semiconductor dies 106. The lid 128 can include dummy semiconductor material that is void of functional circuitry. In some cases, the lid can improve thermal dissipation from the assembly 100. The lid 128 can be attached to the gap fill material 126, the semiconductor dies 104, or the semiconductor dies 106 through an adhesive or dielectric material (e.g., a dielectric block). For example, the dielectric material can be disposed over the gap fill material 126 and coupled with dielectric material disposed over the lid 128. In aspects, the lid 128 can used to increase the thickness of the semiconductor device assembly 100 to meet a design specification or improve the mechanical strength of the semiconductor device assembly 100.

Although illustrated in a particular configuration, a stacked semiconductor device assembly could include a different configuration than shown in FIG. 1A. A stacked semiconductor device assembly could include a different number of stacks of semiconductor dies, a different number of semiconductor dies within each stack, and so on. In some cases, the semiconductor device assembly can include 3, 4, 5, 6, 8, 10, 20, or any number therebetween of stacks of semiconductor dies. In some implementations, each stack of semiconductor dies may include 3, 4, 5, 6, 8, 10, 12, or any number therebetween of semiconductor dies. In yet other aspects, the one or more of the stacks of semiconductor dies could be replaced with a single semiconductor die.

As discussed above, the semiconductor device assembly 100 can be singulated from multiple semiconductor device assemblies assembled through wafer-level processes. FIG. 1B illustrates a simplified schematic plan view of a wafer-level semiconductor device assembly 150 in accordance with an embodiment of the present technology. In aspects, the semiconductor device assembly 150 is illustrated after the semiconductor dies 104 and the semiconductor dies 106 are coupled with the semiconductor die 102 and before the gap fill material 126 of FIG. 1A is disposed around the semiconductor dies 104 and the semiconductor dies 106. In addition to the semiconductor dies 104 and the semiconductor dies 106, additional semiconductor dies are also attached to the semiconductor die 102. The semiconductor dies 104 or the semiconductor dies 106 an have a length or width that is different from the length or width of the semiconductor die 102. Each of the semiconductor dies can have a footprint that is smaller than the footprint of the semiconductor die 102. In this way, multiple semiconductor dies can be attached to the semiconductor die 102 within the footprint of the semiconductor die 102.

An additional semiconductor die 102′ can be located adjacent the semiconductor die 102. Semiconductor dies 104′, semiconductor dies 106′, and any additional semiconductor dies can be disposed at the semiconductor die 102′. In general, a component referenced with a prime can be a separate instance of a like component referred to by the same callout number. For example, the semiconductor die 102′ can be implemented similarly to the semiconductor die 102. Although only one additional semiconductor die 102′ is illustrated in FIG. 1B, the wafer-level semiconductor device assembly 150 can include any number of semiconductor dies. In this way, any number of semiconductor devices can be assembled on a single reconstructed wafer. The semiconductor die 102 and the semiconductor die 102′ (and any number of other semiconductor dies not shown) can form the reconstructed wafer through the deposition of gap fill material 118 outside the footprints of the semiconductor die 102 and the semiconductor die 102′. Although not shown, the gap fill material 118 can be disposed on a carrier substrate to which the semiconductor die 102 and the semiconductor die 102′ are attached.

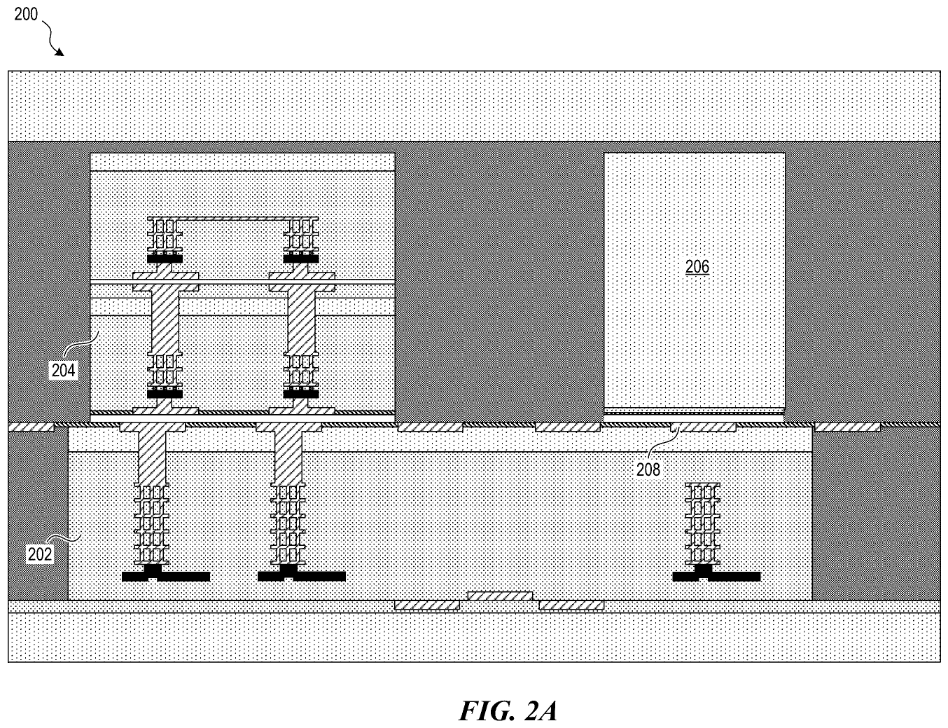

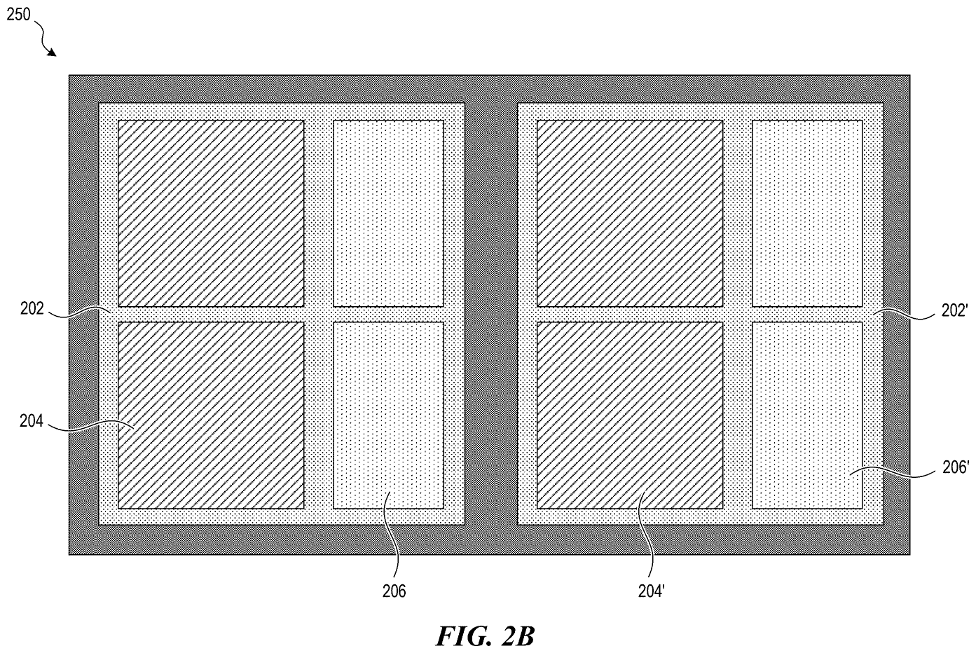

FIG. 2A illustrates a simplified schematic cross-sectional view of a semiconductor device assembly 200 in accordance with an embodiment of the present technology. In general, the semiconductor device assembly 200 can be implemented similarly to the semiconductor device assembly 100 illustrated in FIG. 1A but with the semiconductor dies 106 replaced with a dummy semiconductor component 206. The dummy semiconductor component 206 can be used to implement a greater range of memory devices using a single integration process that caters to the different memory requirement of customers. For example, if the customer only needs half the memory that can be implemented in a maximum memory configuration, this requirement can be satisfied using a similar integration process as for the maximum memory configuration but with half of the memory components replaced with the dummy semiconductor component 206. The semiconductor device assembly 200 includes a semiconductor die 202 (e.g., a logic die) and semiconductor dies 204 electrically and mechanically coupled with the semiconductor die 202.

The dummy semiconductor component 206 is mechanically attached to the semiconductor die 202 adjacent the semiconductor dies 204. The dummy semiconductor component 206 is electrically disconnected from circuitry at the semiconductor die 202. For example, the dummy semiconductor component 206 can be void of functional circuitry or connective circuitry capable of implementing an interconnect between the dummy semiconductor component 206 and the semiconductor die 202. The dummy semiconductor component 206 can have a same height (e.g., a dimension along which the semiconductor dies in the semiconductor dies 204 are stacked) as the semiconductor dies 204. The dummy semiconductor component 206 can have a footprint that fits within at least a portion of the footprint of the semiconductor die 202 exposed beyond the footprint of the semiconductor dies 204. In this way, the dummy semiconductor component 206 can fill empty space on the surface of the semiconductor die 202.

The dummy semiconductor component 206 can be coupled with the semiconductor die 202 through an adhesive or a dielectric material (e.g., dielectric block). In some cases, a dummy pad 208 can be disposed at the semiconductor die 202 within the footprint of the dummy semiconductor component 206. The dummy pad 208 can be disconnected from the functional circuitry at the semiconductor die 202. Although not shown, the dummy semiconductor component 206 can include a dummy pad corresponding to the dummy pad 208, which can couple with the dummy pad 208 to mechanically couple the dummy semiconductor component 206 and the semiconductor die 202.

The dummy semiconductor component 206 can improve the thermal regulation of the semiconductor device assembly 200. For example, the dummy semiconductor component 206 can include semiconductor material, such as silicon, germanium, silicon-germanium alloy, gallium arsenide, gallium nitride, or the like. The semiconductor material can have a higher thermal conductivity than a gap fill material that would otherwise be disposed where the dummy semiconductor component 206 is located. Thus, heat can more easily dissipate from the semiconductor die 202 outside the semiconductor device assembly 200.

The dummy semiconductor component 206 can also improve the consistency of the package. For example, the dummy semiconductor component 206 can have similar material properties to the semiconductor dies 204. Thus, assembly processes performed across the semiconductor device assembly 200 can affect different portions of the semiconductor device assembly similarly. For example, dishing resulting from chemical-mechanical planarization (CMP) or back grinding can be limited.

FIG. 2B illustrates a simplified schematic plan view of a wafer-level semiconductor device assembly 250 in accordance with an embodiment of the present technology. The semiconductor device assembly 200 of FIG. 2A can be singulated from the semiconductor device assembly 250. In aspects, the semiconductor device assembly 250 is illustrated after the semiconductor dies 204 and the dummy semiconductor component 206 are coupled with the semiconductor die 202 and before gap fill material is disposed around the semiconductor dies 204 and the dummy semiconductor component 206. In addition to the semiconductor dies 204, an additional semiconductor dies is also attached to the semiconductor die 202. Moreover, one or more additional dummy semiconductor components can be attached to the semiconductor die 202. As discussed above, the dummy semiconductor component 206 (and additional dummy semiconductor components) can have a footprint that fits within the footprint of the semiconductor die 202 exposed beyond the semiconductor dies 204 (and additional stacks of semiconductor dies).

An additional semiconductor die 202′ can be located adjacent the semiconductor die 202. Semiconductor dies 204′ and any additional semiconductor dies and the dummy semiconductor component 206′ and any additional dummy semiconductor components can be attached to the additional semiconductor die 202′. Although only one additional semiconductor die 202′ is illustrated in FIG. 2B, the wafer-level semiconductor device assembly 250 can include any number of semiconductor dies. In this way, any number of semiconductor devices can be assembled on a single reconstructed wafer. The semiconductor die 202 and the semiconductor die 202′ (and any number of other semiconductor dies not shown) can form the reconstructed wafer through the deposition of gap fill material outside the footprints of the semiconductor die 202 and the semiconductor die 202′. The reconstructed wafer can then be sawed to singulate the individual semiconductor devices.

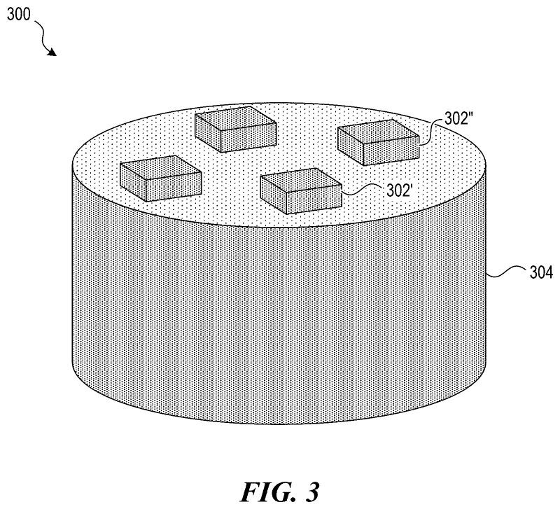

This disclosure now turns to a series of steps for fabricating semiconductor device assemblies in accordance with embodiments of the present technology. Specifically, FIGS. 3-11 illustrate simplified schematic perspective and cross-sectional views of a series of steps for fabricating semiconductor device assemblies in accordance with embodiments of the present technology. The steps are illustrated with respect to specific embodiments for ease of description. However, the steps described with respect to FIGS. 3-11 could be performed to fabricate semiconductor device assemblies in accordance with other embodiments.

Beginning with FIG. 3 at stage 300, semiconductor die 302′ (e.g., an example of the semiconductor die 102 of FIG. 1A), semiconductor die 302″, and any additional semiconductor dies (referred to collectively as semiconductor dies 302) are attached to a wafer-level carrier substrate 304 (e.g., a non-singulated example of the carrier substrate 120 of FIG. 1A). The semiconductor dies 302 can be attached to the carrier substrate 304 at different lateral locations (e.g., based on fiducials) through an adhesive or through dielectric bonds. The semiconductor dies 302 can be selected from a plurality of semiconductor dies diced from a wafer. In aspects, the semiconductor dies 302 can have a low yield. Thus, some of the semiconductor dies diced from the wafer can be inoperable and their inclusion within the semiconductor device assembly can waste space and assembly resources. To reduce this waste, the semiconductor dies 302 can be selected based on their quality (e.g., whether the die is operable or inoperable). The quality of the semiconductor dies 302 can be determined through probing a test pad coupled with functional circuitry at the semiconductor dies 302. If the probing results in the expected results, the semiconductor dies 302 can be determined as operable. If operable, the semiconductor dies 302 are determined as “known good dies” and can be included within the assembly. Thus, by including only operable dies in the semiconductor device assembly, the overall yield of the process can be improved.

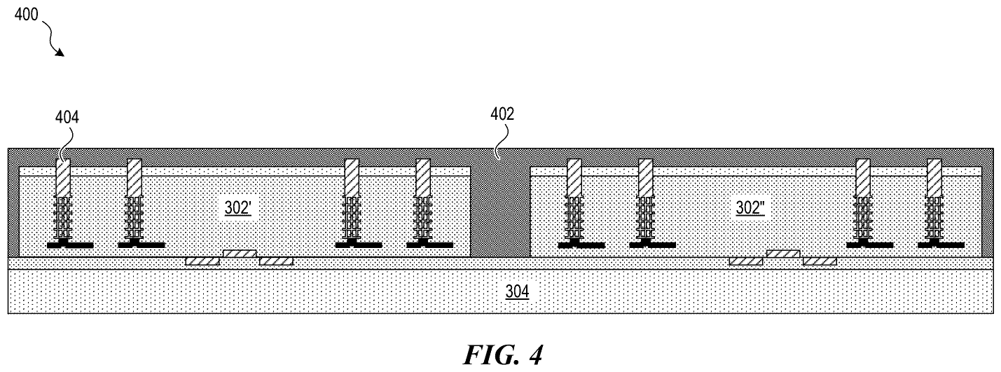

Turning next to FIG. 4 at stage 400, the semiconductor dies 302 are at least partially surrounded by a gap fill material 402 (e.g., a dielectric material or oxide fill) to form a reconstructed wafer. In some cases, the semiconductor dies 302 can be thinned to expose contacts (e.g., TSVs 404) at a distal end of the semiconductor dies 302 opposite the carrier substrate 304. In some aspects, the semiconductor dies 302 can be thinned through back grinding. In some cases, however, back grinding can result in suboptimal surface roughness, grinding marks, or die corner chipping. In another aspect, the semiconductor dies 302 can be thinned through CMP. In some of these cases, however, CMP processes can trap slurry between adjacent ones of the semiconductor dies 302, which can reduce the strength of the assembly. In yet other aspects, the semiconductor dies 302 can be thinned through dry etching. In some cases, dry etching can result in removal of at least some of a dielectric material (not shown) surrounding the TSVs 404, which can result in mechanical or electrical failure or diffusion of the TSVs 404. In some cases, the removal of the dielectric material surrounding the TSVs 404 can be prevented through a selective dry etch. In general, any technique can be used to thin the semiconductor dies 302 and expose the TSVs 404.

The contacts can couple through connective circuitry to functional circuitry at the semiconductor dies 302. To form a protective coating over the distal end of the semiconductor dies 302, a layer of dielectric material, such as silicon oxide, silicon nitride, silicon carbide, or silicon carbon nitride, can be disposed over the distal end of the semiconductor dies 302. The layer of dielectric material can extend over the TSVs 404 exposed at the distal end of the semiconductor dies 302.

The gap fill material 402 can be disposed at the carrier substrate 304 beyond the footprint of the semiconductor dies 302. The gap fill material 402 can extend along a side of the semiconductor dies 302 between a side attached to the carrier substrate 304 and the opposite side. In aspects, the gap fill material 402 can fill the gap between the semiconductor dies 302. As illustrated, the gap fill material 402 is also disposed over the distal end of the semiconductor dies 302. The gap fill material 402 can be disposed through any appropriate method, for example, using chemical vapor deposition, physical vapor deposition, dispensing, oxidation, spin coating, and/or other suitable techniques. Once the gap fill material 402 is deposited, the gap fill material 402 and the semiconductor dies 302 can form a reconstructed wafer of “known good dies” on which additional assembly processes can be performed. This process is significantly different from other assembly processes in which a non-singulated, functional wafer is used to carry the semiconductor dies 302.

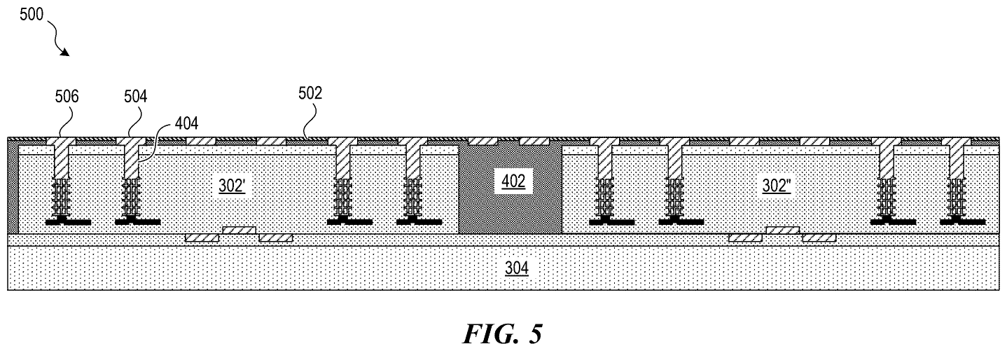

Turning next to FIG. 5 at stage 500, the gap fill material 402 is thinned and a layer of dielectric material 502 and contacts 504 are disposed at the distal end of the semiconductor dies 302 and at the gap fill material 402. The gap fill material 402 can be thinned at the distal end opposite the carrier substrate 304 through any appropriate method (e.g., back grinding, CMP, etching, or the like). In some cases, the gap fill material 402 can be thinned until the semiconductor dies 302 are exposed. In other cases, at least a portion of the gap fill material 402 can remain over the distal end of the semiconductor dies 302 opposite the carrier substrate 304. In general, the gap fill material 402 alone or the gap fill material 402 and the semiconductor dies 302 can form a planar surface on which additional material can be disposed.

As illustrated, a layer of dielectric material 502 is disposed at the gap fill material 402. The layer of dielectric material 502 can be a dielectric block that includes silicon oxide, silicon nitride, silicon carbide, silicon carbon nitride, or the like. The dielectric material 502 (and, in cases where the gap fill material is disposed over the semiconductor dies 302, the gap fill material 402) can be etched to expose the TSVs 404 at the distal end of the semiconductor dies 302. Contacts 504 can then be disposed in the openings etched to expose the TSVs 404 to enable electrical contact with the functional circuitry at the semiconductor dies 302. The contacts 504 can be implemented by disposing conductive material within the openings. In some cases, the contacts can be implemented using a copper damascene process.

In some embodiments, the layer of dielectric material 502 can similarly be etched at locations that do not include the TSVs 404. For example, the openings can be created within the footprint of the semiconductor dies 302 at locations that do not include the TSVs 404 beyond the footprint of the semiconductor dies 302 above the gap fill material 402. Conductive material can be disposed at the openings to implement dummy pads 506 that are disconnected from the functional circuitry at the semiconductor dies 302. In aspects, the dummy pads 506 can be disposed to maintain similar pitch between the contacts 504 and the dummy pads 506 across the surface. In this way, the dummy pads 506 can reduce dishing caused by planarization or other assembly processes at the surface at which the contacts 504 and the dummy pads 506 are disposed. In yet other aspects, the dummy pads 506 can be used to mechanically couple additional components to the semiconductor dies 302 or the gap fill material 402.

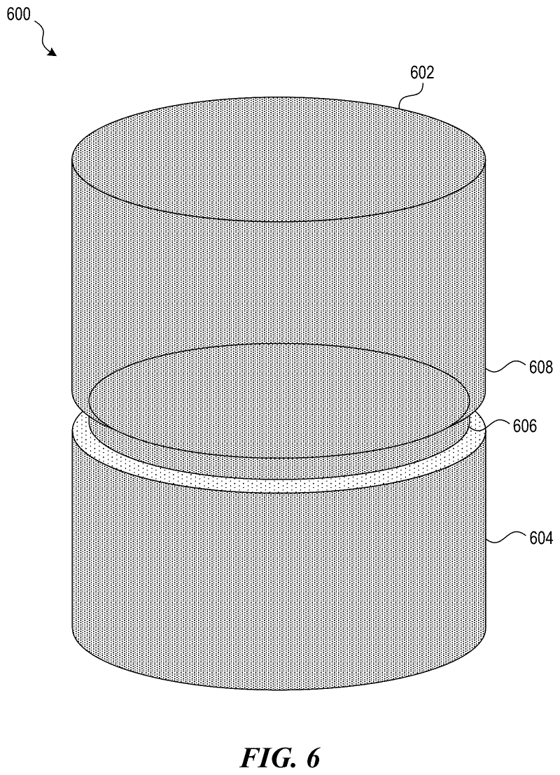

Turning next to FIG. 6 at stage 600, a stack of semiconductor wafers 602 is provided. The stack of semiconductor wafers 602 is adhered to a carrier wafer 604 to enable the semiconductor wafers to withstand processing. A semiconductor wafer 606 is adhered to the carrier wafer 604. TSVs or other contacts coupled with functional circuitry within the semiconductor wafer 606 may be exposed at the semiconductor wafer 606 and contact pads may be disposed thereat. A second semiconductor wafer 608 may be electrically and mechanically coupled to the first semiconductor wafer 606 (e.g., in a face-to-back configuration) at the contact pads through wafer-wafer bonding (e.g., hybrid bonding). The stack of semiconductor wafers 602 can then be processed and diced to singulate individual stacks of semiconductor dies.

For example, the stack of semiconductor wafers 602 can be adhered to back grinding tape, and the semiconductor wafer 608 can be thinned through any appropriate method, such as back grinding, CMP, or the like. After thinning, the back grinding tape can be removed from the stack of semiconductor wafers 602, and the stack of semiconductor wafers 602 can be attached to dicing tape. Once attached to the dicing tape, the stack of semiconductor wafers 602 can be diced into multiple stacks of semiconductor dies.

Although only two semiconductor wafers are illustrated, additional semiconductor wafers can be attached to the stack of semiconductor wafers 602 through similar processes as described with respect to the semiconductor wafer 606 and the semiconductor wafer 608. In this way, stacks of semiconductor dies having a different number of semiconductor dies can be assembled.

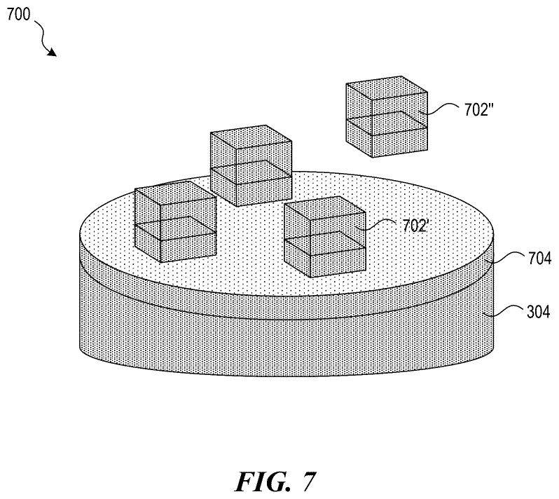

Turning next to FIG. 7 at stage 700, semiconductor dies 702′, semiconductor dies 702″, and any other number of semiconductor dies (referred to collectively as the stacks of semiconductor dies 702) are assembled onto a reconstructed wafer of semiconductor dies 704. The semiconductor dies 702 can be singulated from the stack of semiconductor wafers 602 of FIG. 6. The reconstructed wafer of semiconductor dies 704 can correspond to the reconstructed wafer of semiconductor dies formed at stage 500 illustrated in FIG. 5 and supported by the carrier substrate 304. The semiconductor dies 702 can be mechanically and electrically coupled to the reconstructed wafer of semiconductor dies 704 (e.g., through the layer of dielectric material 502 and the contacts 504 illustrated in FIG. 5). For example, multiple of the semiconductor dies 702 can be coupled with a single semiconductor die at different lateral locations. The semiconductor dies 702 can be formed through chip-wafer bonding (e.g., hybrid bonding).

In some cases, the semiconductor dies 702 singulated from the stack of semiconductor wafers 602 at FIG. 6 can be tested before being included within the semiconductor device assembly. The semiconductor dies 702 can be selected based on quality. For example, the operability of each of the semiconductor dies 702 can be determined through probing the semiconductor dies, and once the semiconductor dies 702 are determined to be operable, they can be coupled with the reconstructed wafer of semiconductor dies 704. In this way, the semiconductor dies 702 coupled with the reconstructed wafer of semiconductor dies 704 can be “known good cubes” (or stacks determined to be operable), which can improve yield.

In some cases, one or more of the semiconductor dies 702 can be replaced with a dummy semiconductor component, as discussed with respect to FIGS. 2A and 2B. In aspects, the dummy semiconductor component can be coupled with the reconstructed wafer of semiconductor dies 704 through similar processes as described for the semiconductor dies 702. However, given that the dummy semiconductor component does not electrically couple with the reconstructed wafer of semiconductor dies 704, the dummy semiconductor component can be coupled through dummy pads or dielectric material instead of contacts coupled with functional circuitry at the reconstructed wafer of semiconductor dies 704.

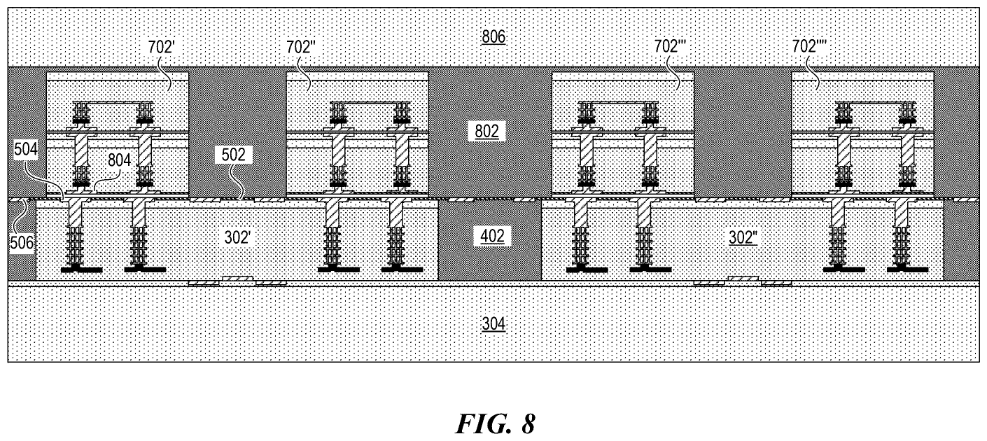

Turning next to FIG. 8 at stage 800, the semiconductor dies 702 are at least partially surrounded by a gap fill material 802 (e.g., a dielectric material or oxide fill). As discussed at FIG. 3, multiple stacks of semiconductor dies (e.g., semiconductor dies 702′ and semiconductor dies 702″) can be attached to a single semiconductor die (e.g., semiconductor die 302′). For example, the semiconductor dies 702′ can include contacts 804 coupled through connective circuitry to functional circuitry at the semiconductor dies 702′, and the contacts 804 can couple with the contacts 504 at the semiconductor die 302′ to form interconnects coupling the functional circuitry at the semiconductor dies 702′ with the semiconductor die 302′. Moreover, a layer of dielectric material at the semiconductor dies 702′ can mechanically couple with the layer of dielectric material 502 at the semiconductor die 302′. In some cases, the semiconductor dies 702 and the semiconductor dies 302 can mechanically couple through the dummy pads 506. Similar operations can be performed to couple the semiconductor dies 702″ with the semiconductor die 302′, and to couple other sets of semiconductor dies (e.g., semiconductor dies 702″ and semiconductor dies 702″″) with additional semiconductor dies in the reconstructed wafer of semiconductor dies 704 (e.g., semiconductor die 302″).

The gap fill material 802 (e.g., dielectric material, an oxide fill, or the like) can be disposed at the semiconductor dies 302 and at the gap fill material 402 beyond the footprints of the semiconductor dies 702. In some cases, the gap fill material 802 can be disposed over a distal end of the semiconductor dies 702 opposite the carrier substrate 304. Thus, a portion of the gap fill material 802 can at least partially surround the distal end of the semiconductor dies 702. In some cases, the gap fill material 802 can be disposed over the distal end of the semiconductor dies 702, and the gap fill material 802 can be thinned until none of the gap fill material 802 or a small portion of the gap fill material 802 remains over the distal end of the semiconductor dies 702.

As illustrated, a lid 806 is disposed over the semiconductor dies 702. For example, the lid 806 can be attached to a distal end of the gap fill material 802 or the semiconductor dies 702 opposite the carrier substrate 304 through an adhesive or through a dielectric material (e.g., dielectric block). The lid 806 can include a semiconductor material, such as silicon, germanium, silicon-germanium alloy, gallium arsenide, gallium nitride, or the like. The lid 806 can improve the mechanical strength of the assembly or increase the thickness of the assembly to meet a design requirement of the semiconductor device assembly.

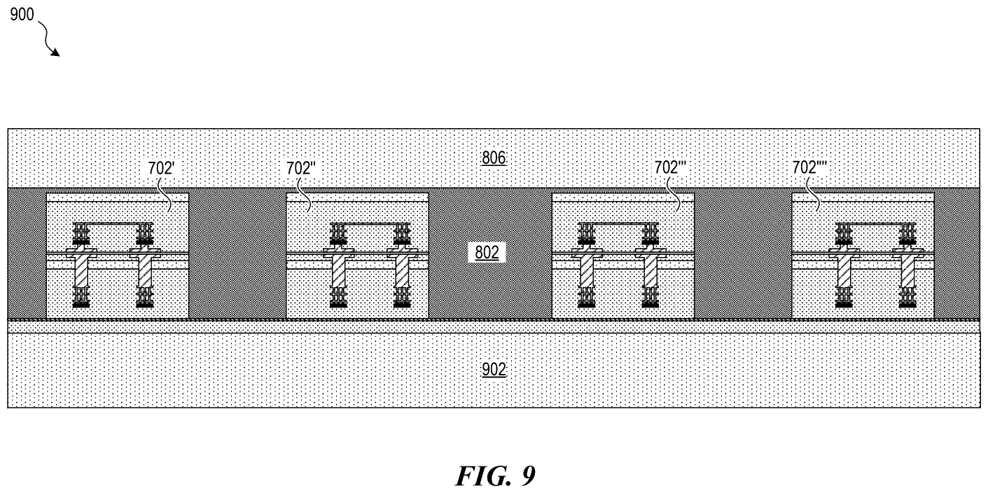

In general, FIGS. 7 and 8 illustrate techniques for attaching the semiconductor dies 702 to semiconductor dies 302 through chip-wafer processes. Alternatively, the semiconductor dies 702 can be attached to semiconductor dies 302 through wafer-wafer processes. For example, turning to FIG. 9 at stage 900, the semiconductor dies 702 can be coupled to a carrier substrate 902 and filled with the gap fill material 802 to form a reconstructed wafer. The semiconductor dies 702 can be coupled with the carrier substrate 902 at lateral locations that correspond to the semiconductor dies (e.g., semiconductor dies 302 of FIG. 5) to which they attach. For example, the semiconductor dies 702′ and the semiconductor dies 702″ can be disposed at lateral locations that are within a footprint of a first semiconductor die to which they attach (e.g., semiconductor die 302′ of FIG. 5), and the semiconductor dies 702′″ and the semiconductor dies 702″″ can be disposed at lateral locations that are within a footprint of a second semiconductor die to which they attach (e.g., semiconductor die 302″ of FIG. 5). The semiconductor dies 702 can be selected as “known good cubes” before being attached to the carrier substrate 902, thus improving yield. The semiconductor dies 702 can attach to the carrier substrate 902 through an adhesive or dielectric material.

The gap fill material 802 can be disposed at the carrier substrate 902 beyond the footprint of the semiconductor dies 702 to form a reconstructed wafer. In some cases, the gap fill material 802 can be disposed over a distal end of the semiconductor dies 702 opposite the carrier substrate 902. The lid 806 can be disposed over the semiconductor dies 702 and the gap fill material 802 to increase the thickness of or add mechanical strength to the assembly. Once assembled, the semiconductor dies 702 and the gap fill material 802 can form a continuous wafer-like structure at which wafer-level processes, such as wafer-wafer bonding, can be performed.

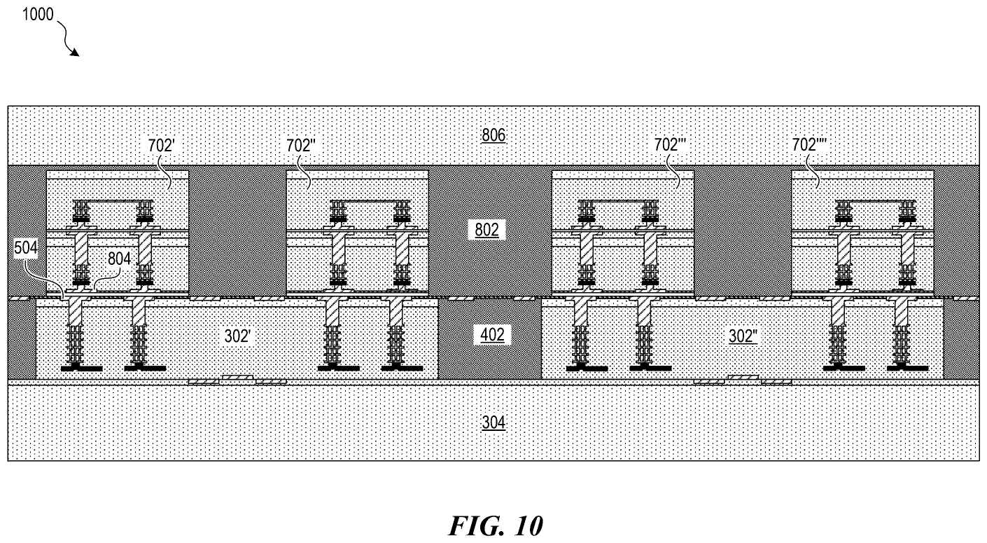

Turning next to FIG. 10 at stage 1000, the reconstructed wafer formed from the semiconductor dies 702 and the gap fill material 802 is coupled with the reconstructed wafer formed from the semiconductor dies 302 and the gap fill material 402. For example, the semiconductor dies 702 can be separated from the carrier substrate 902 to which they are attached at stage 900 of FIG. 9, and the contacts 804 can be disposed at the exposed surface. The semiconductor dies 702 and the semiconductor dies 302 can then be coupled through wafer-wafer bonding (e.g., hybrid bonding). For example, the semiconductor dies 702′ and the semiconductor dies 702″ can couple (e.g., electrically and mechanically) with the semiconductor die 302′ through the contacts 804 and the contacts 504. The semiconductor dies 702′″ and the semiconductor dies 702″″ can similarly be attached to the semiconductor die 302″.

In aspects, coupling the semiconductor dies 702 to the semiconductor dies 302 through chip-wafer processes and wafer-wafer processes can result in similar assemblies. In some cases, wafer-wafer processes can have advantages over chip-wafer processes. For example, wafer-wafer processes can have a higher yield. Moreover, interconnects formed through wafer-wafer processes can have greater alignment. In general, however, once the semiconductor dies 702 and the semiconductor dies 302 are coupled, through chip-wafer or wafer-wafer processes, the assembly can be singulated and packaged into individual devices.

Although each of the semiconductor dies 302 is illustrated as being coupled with the semiconductor dies 702 in FIGS. 8 and 10, in some embodiments, one or more of the semiconductor dies 302 can be coupled with dummy semiconductor components void of functional circuitry. In some cases, the dummy semiconductor components can replace one or more of the semiconductor dies 702. In other cases, dummy semiconductor components can be used to fill space and provide thermal regulation between the semiconductor dies 702. In general, dummy semiconductor components can be coupled with the semiconductor dies 302 through similar processes as described for the semiconductor dies 702 but without forming electrical interconnects between the dummy semiconductor components and the semiconductor dies 302.

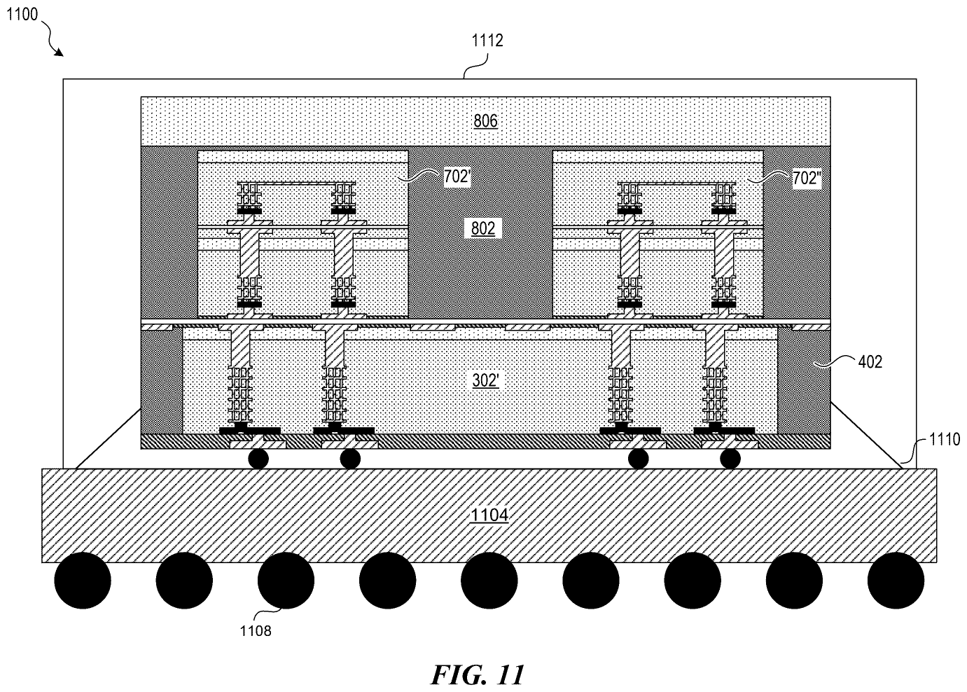

Turning next to FIG. 11 at stage 1100, the assembly is singulated and packaged into a single semiconductor device. For example, the assembly at stage 800 of FIG. 8 or stage 1000 of FIG. 10 can be sawed at the gap fill material 402, the gap fill material 802, and the lid 806 between the semiconductor dies 302. As illustrated, a semiconductor device that includes the semiconductor die 302′, the semiconductor dies 702′, and the semiconductor dies 702″ is singulated and packaged. By sawing through the gap fill material 402 and the gap fill material 802, the gap fill material 402 and the gap fill material 802 form peripheral portions along sidewalls of the semiconductor die 302′ and the semiconductor dies 702, respectively. Contacts 1102 are disposed at and coupled with circuitry at the semiconductor die 302′ to provide external connectivity to the semiconductor die 302′ and the semiconductor dies 702.

The semiconductor die 302′ is attached to a package-level substrate 1104 (e.g., printed circuit board (PCB), semiconductor substrate, or the like). Interconnects 1106 (e.g., solder, conductive pillars, or the like) can be formed between contacts 1102 at a bottom surface of the semiconductor die 302′ and contacts (not shown) at the package-level substrate 1104 to enable electrical signals to pass between the semiconductor die 302′ (or the semiconductor dies 702) and the package-level substrate 1104. The package-level substrate 1104 can further include package-level contact pads (not shown) that provide external connectivity (e.g., power, ground, and input/output (I/O) signals) through solder balls 1108 or other connective structures to the semiconductor die 302′ and the semiconductor dies 702 (e.g., power, ground, and I/O signals). Traces, lines, vias, and other electrical connection structures in the package-level substrate 1104 can electrically connect the package-level contact pads to contact pads at an upper surface of the package-level substrate 1104.

An underfill material 1110 (e.g., capillary underfill) can be provided between the semiconductor die 302′ and the package-level substrate 1104 to provide electrical insulation to the interconnects 1106 and structurally support the device. The semiconductor die 302′, the semiconductor dies 702, and the package-level substrate 1104 can be at least partially encapsulated by an encapsulant material 1112 (e.g., mold resin compound or the like) to prevent electrical contact therewith and provide mechanical strength and protection to the assembly.

Although in the foregoing example embodiment semiconductor device assemblies have been illustrated and described as including a particular configuration of semiconductor dies, in other embodiments, assemblies can be provided with different configurations of semiconductor dies. For example, the semiconductor device assemblies illustrated in any of the foregoing examples could be implemented with, for example, a vertical semiconductor dies, a plurality of semiconductor dies, a single semiconductor die, mutatis mutandis.

In accordance with one aspect of the present disclosure, the semiconductor devices illustrated in the assemblies of FIGS. 1A-11 could be memory dies, such as DRAM dies, NAND memory dies, NOT-OR (NOR) memory dies, magnetic random-access memory (MRAM) dies, phase change memory (PCM) dies, ferroelectric random-access memory (FeRAM) dies, SRAM dies, or the like. In an embodiment in which multiple dies are provided in a single assembly, the semiconductor devices could include memory dies of a same kind (e.g., both NAND, both DRAM, etc.) or memory dies of different kinds (e.g., one DRAM and one NAND, etc.). In accordance with another aspect of the present disclosure, the semiconductor dies of the assemblies illustrated and described above could be logic dies (e.g., controller dies, processor dies, etc.), or a mix of logic and memory dies (e.g., a memory controller die and a memory die controlled thereby).

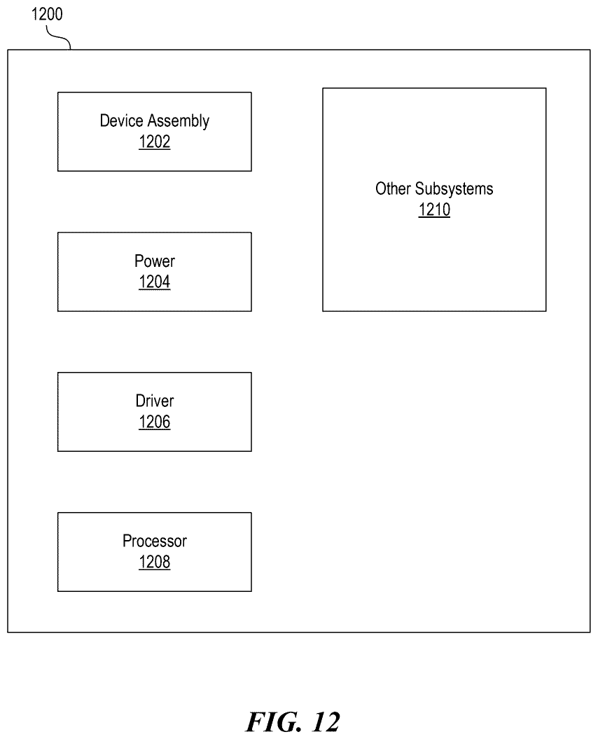

Any one of the semiconductor devices and semiconductor device assemblies described above with reference to FIGS. 1A-11 can be incorporated into any of a myriad of larger and/or more complex systems, a representative example of which is system 1200 shown schematically in FIG. 12. The semiconductor dies as provided in FIGS. 1A-11 can communicate with one or more devices within the system 1200 using one or more standard protocols. For example, the memory may communicate using a high bandwidth memory (HBM) protocol. Alternatively, the memory may communicate using any other appropriate protocol. The system 1200 can include a semiconductor device assembly 1202 (e.g., a discrete semiconductor device), a power source 1204, a driver 1206, a processor 1208, and/or other subsystems or components 1210. The semiconductor device assembly 1202 can include features generally similar to those of the semiconductor device assemblies described above with reference to FIGS. 1A-11. The resulting system 1200 can perform any of a wide variety of functions, such as memory storage, data processing, and/or other suitable functions. Accordingly, representative systems 1200 can include, without limitation, hand-held devices (e.g., mobile phones, tablets, digital readers, and digital audio players), computers, vehicles, appliances, and other products. Components of the system 1200 may be housed in a single unit or distributed over multiple, interconnected units (e.g., through a communications network). The components of the system 1200 can also include remote devices and any of a wide variety of computer-readable media.

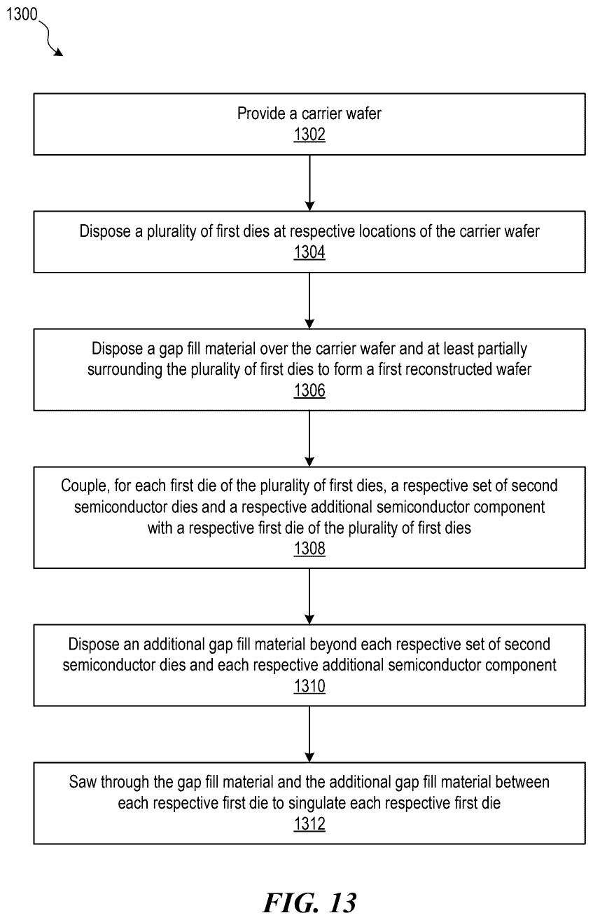

FIG. 13 illustrates a method 1300 for fabricating a semiconductor device assembly in accordance with an embodiment of the present technology. Although illustrated in a particular configuration, one or more operations of the method 1300 may be omitted, repeated, or reorganized. Additionally, the method 1300 may include other operations not illustrated in FIG. 13, for example, operations detailed in one or more other methods described herein.

At 1302, a carrier wafer is provided. The carrier wafer can include a semiconductor material. The carrier wafer can have adequate thickness to support the assembly during processing.

At 1304, a plurality of first semiconductor dies (e.g., logic dies) are disposed at respective locations of the carrier wafer. For example, a plurality of first dies can be selected as “known good dies” and assembled onto different locations of the carrier wafer. The first dies can be attached to the carrier wafer through an adhesive or a dielectric material.

At 1306, a gap fill material is disposed over the carrier wafer and at least partially surrounding the plurality of first dies to form a first reconstructed wafer. The gap fill material can include a dielectric material or an oxide fill. In some cases, the gap fill material includes silicon oxide. The gap fill material can be disposed outside the footprints of the first dies and extend along the edges of the first dies. In some cases, the gap fill material can be disposed over a distal end of the first dies opposite the carrier wafer. By filling the space between the first dies, a reconstructed wafer can be formed from first dies that have been determined as operable.

At 1308, respective sets of second semiconductor dies and a respective additional semiconductor component are coupled with each respective logic die of the plurality of logic dies. In aspects, the second semiconductor dies include memory dies (e.g., DRAM dies or SRAM dies). The additional semiconductor component can include a component implemented using semiconductor material. For example, the additional semiconductor component can include semiconductor dies, such as memory dies. In some cases, the second semiconductor dies and the additional semiconductor component can include memory dies of the same or of different type. For example, the second semiconductor dies can include DRAM dies, and the additional semiconductor component can include SRAM dies. In some cases, the additional semiconductor component can include a dummy semiconductor component void of functional circuitry. In this way, the dummy semiconductor component can fill space or improve thermal regulation instead of increasing the functionality of the device.

The respective sets of second semiconductor dies and the respective additional semiconductor component can be coupled with the first dies through chip-wafer or wafer-wafer processes. For example, using chip-wafer processing, the respective sets of second semiconductor dies and the respective additional semiconductor component can be individually attached to the wafer of first dies. Alternatively, using wafer-wafer processing, the respective sets of second semiconductor dies and the respective additional semiconductor component can be formed into a reconstructed wafer that is coupled with the reconstructed wafer formed from the first dies. For example, the respective sets of second semiconductor dies and the respective additional semiconductor component can be attached to a second carrier wafer and surrounded by a gap fill material. The carrier wafer can then be removed, and the reconstructed wafer can be attached to the reconstructed wafer of first dies.

At 1310, an additional gap fill material is disposed beyond each respective set of second semiconductor dies and each respective additional semiconductor component. When the assembly is formed through chip-wafer processes, the additional gap fill material can be disposed on the logic dies or on the gap fill material disposed at 1306. Alternatively, when the assembly is formed through wafer-wafer processes, the additional gap fill material can be disposed at the second carrier wafer when reconstructing a wafer from the second semiconductor dies and the additional semiconductor components. The additional gap fill material can be exposed beyond the footprint of the respective sets of second semiconductor dies and each respective additional semiconductor component. In some cases, the additional gap fill material can be disposed at a distal end of one or more of the second semiconductor dies or the additional semiconductor components.

At 1312, the assembly can be sawed through the gap fill material and the additional gap fill material to singulate each respective first die. In this way, a single semiconductor device including a first die, second semiconductor dies, and an additional semiconductor component can be singulated. The single device can then be packaged and shipped.

Specific details of several embodiments of semiconductor devices, and associated systems and methods, are described above. Depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, CMP, or other suitable techniques.

The technology disclosed herein relates to semiconductor devices, systems with semiconductor devices, and related methods for manufacturing semiconductor devices. The term “semiconductor device” generally refers to a solid-state device that includes one or more semiconductor materials. Examples of semiconductor devices include logic devices, memory devices, and diodes, among others. Furthermore, the term “semiconductor device” can refer to a finished device or to an assembly or other structure at various stages of processing before becoming a finished device. Depending upon the context in which it is used, the term “substrate” can refer to a structure that supports electronic components (e.g., a die), such as a PCB or wafer-level substrate, a die-level substrate, or another die for die-stacking or three-dimensional integration (3DI) applications.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor device assembly, comprising:
a first semiconductor die having a first side and a second side;
dielectric peripheral material disposed against sidewalls of the first semiconductor die and extending beyond a first footprint of the first semiconductor die between the first side and the second side;
one or more second semiconductor dies electrically and mechanically coupled with the first semiconductor die at a first location of the second side;
an additional semiconductor component mechanically coupled with the first semiconductor die at a second location of the second side that is different from the first location; and
a gap fill material disposed over the first semiconductor die and over the dielectric peripheral material beyond a second footprint of the one or more second semiconductor dies and a third footprint of the additional semiconductor component, the gap fill material at least partially surrounding the one or more second semiconductor dies and the additional semiconductor component.

2. The semiconductor device assembly of claim 1, wherein the additional semiconductor component comprises one or more third semiconductor dies.

3. The semiconductor device assembly of claim 2, wherein:
the one or more second semiconductor dies comprise memory dies of a first type; and
the one or more third semiconductor dies comprise memory dies of a second type different from the first type.

4. The semiconductor device assembly of claim 1, wherein the additional semiconductor component comprises a dummy semiconductor component void of functional circuitry.

5. The semiconductor device assembly of claim 4, wherein the first semiconductor die comprises a dummy conductive pad electrically disconnected from circuitry at the first side of the first semiconductor die, the dummy conductive pad disposed at the second location of the second side within the third footprint of the additional semiconductor component.

6. The semiconductor device assembly of claim 1, wherein:
the one or more second semiconductor dies comprises a stack of second semiconductor dies with a first height along a dimension in which the second semiconductor dies in the stack of second semiconductor dies are stacked; and
the additional semiconductor component has a second height along the dimension, the second height equal to the first height.

7. The semiconductor device assembly of claim 1, further comprising one or more dummy conductive pads disconnected from circuitry at the first side of the first semiconductor die, the one or more dummy conductive pads disposed at the second side of the first semiconductor die or at the dielectric peripheral material beyond the second footprint of the one or more second semiconductor dies and the third footprint of the additional semiconductor component.

8. A method for fabricating a semiconductor device assembly, comprising:
providing a carrier wafer;
disposing a plurality of first semiconductor dies at respective locations of the carrier wafer;
disposing a gap fill material over the carrier wafer and at least partially surrounding the plurality of first semiconductor dies;
coupling, for each respective logic die of the plurality of logic dies, a respective first set of one or more semiconductor dies and a respective additional semiconductor component with a respective first semiconductor die of the plurality of first semiconductor dies, the respective first set of one or more semiconductor dies disposed at a respective first location of the respective first semiconductor die, the respective additional semiconductor component disposed at a respective second location of the respective first semiconductor die different from the respective first location;
disposing an additional gap fill material over each respective first semiconductor die and over the gap fill material beyond each respective first set of one or more semiconductor dies and each respective additional semiconductor component; and
sawing through the gap fill material and the additional gap fill material between each respective first semiconductor die to singulate each respective semiconductor die.

9. The method of claim 8, further comprising:
providing a wafer of semiconductor dies including the plurality of first semiconductor dies;
dicing the plurality of first semiconductor dies from the wafer of semiconductor dies;
probing the plurality of first semiconductor dies to determine a quality of the plurality of first semiconductor dies; and
determining that the plurality of first semiconductor dies are operable, wherein disposing the plurality of first semiconductor dies at respective locations of the carrier wafer is responsive to determining that the plurality of first semiconductor dies are operable.

10. The method of claim 8, further comprising:
disposing the gap fill material over a distal end of the plurality of first semiconductor dies opposite the carrier wafer;
removing a portion of the gap fill material to expose respective contacts at the distal end of each respective first semiconductor die of the plurality of first semiconductor dies, the respective contacts coupled with respective circuitry at the respective first semiconductor die; and
coupling, for each respective first semiconductor die of the plurality of first semiconductor dies, the respective first set of one or more semiconductor dies with the respective first semiconductor die at the respective contacts.

11. The method of claim 8, further comprising disposing one or more respective dummy contacts at a distal end of the gap fill material opposite the carrier wafer or at a distal end of a respective first semiconductor die of the plurality of first semiconductor dies opposite the carrier wafer, the one or more respective dummy contacts disconnected from respective circuitry at the respective first semiconductor die.

12. The method of claim 8, further comprising:
separating the carrier wafer from the plurality of first semiconductor dies; and
disposing, for each respective first semiconductor die of the plurality of first semiconductor dies, respective contacts at the respective first semiconductor die, the respective contacts coupled with respective circuitry at the respective first semiconductor die.

13. The method of claim 8, wherein the respective additional semiconductor component comprises a respective dummy semiconductor component void of functional circuitry.

14. The method of claim 8, wherein the respective additional semiconductor component comprises a respective second set of one or more semiconductor dies.

15. The method of claim 14, wherein:
the respective first set of one or more semiconductor dies comprises memory dies of a first type; and
the respective second set of one or more semiconductor dies comprises memory dies of a second type different from the first type.

16. A method for fabricating a semiconductor device assembly, comprising:
providing a first carrier wafer;
disposing a plurality of first semiconductor dies at respective first locations of the first carrier wafer;
disposing a gap fill material over the first carrier wafer and at least partially surrounding the plurality of first semiconductor dies to form a first reconstructed wafer;
providing a second carrier wafer;
disposing respective sets of one or more second semiconductor dies and an additional semiconductor component at respective second locations of the second carrier wafer, the respective second locations of the second carrier wafer corresponding to the respective first locations of the first carrier wafer;
disposing an additional gap fill material over the second carrier wafer and at least partially surrounding the respective sets of the one or more second semiconductor dies and the additional semiconductor component to create a second reconstructed wafer;
separating the second carrier wafer from the respective sets of the one or more second semiconductor dies and the additional semiconductor component and the additional gap fill;
responsive to separating the second carrier wafer from the respective sets of the one or more second semiconductor dies and the additional semiconductor component and the additional gap fill material, coupling the second reconstructed wafer and the first reconstructed wafer such that each of the respective sets of the one or more second semiconductor dies and the additional semiconductor component couples with a respective first semiconductor die of the plurality of first semiconductor dies; and
sawing through the gap fill material and the additional gap fill material between each respective first semiconductor die to singulate each respective first semiconductor die.

17. The method of claim 16, wherein the additional semiconductor component comprises a dummy semiconductor component void of functional circuitry.

18. The method of claim 16, wherein the additional semiconductor component comprises one or more third semiconductor dies.

19. The method of claim 18, wherein:
the one or more second semiconductor dies comprises memory dies of a first type; and
the one or more second semiconductor dies comprises memory dies of a second type different from the first type.

20. The method of claim 17, further comprising disposing one or more respective dummy contacts at a distal end of the gap fill material opposite the carrier wafer or at a distal end of the respective first semiconductor die of the plurality of first semiconductor dies opposite the carrier wafer, the one or more respective dummy contacts disconnected from respective circuitry at the respective first semiconductor die.
